(19) United States
(12) Patent Application Publication
(10) Pub. No.: US 2026/0305148 A1
(43) Pub. Date: Oct. 1, 2026

(54) HEAT DISSIPATION FILM, DISPLAY MODULE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Xue Meng, Beijing (CN); Rongkun Fan, Beijing (CN); Jialin Wang, Beijing (CN); Qiang Pu, Beijing (CN); Fei Zeng, Beijing (CN); Guodong Zhou, Beijing (CN); Wei Zhou, Beijing (CN); Haitao Liang, Beijing (CN); Yongsong Meng, Beijing (CN); Yuxuan Men, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/479,570

(22) PCT Filed: Jan. 7, 2025
(86) PCT No.: PCT/CN2025/071054

§ 371 Date: Oct. 28, 2025

(30) Foreign Application Priority Data
Jan. 18, 2024 (CN) 202410077514.0

(51) Int. Cl. H10K 59/80; H05K 9/00; H10K 102/00

(52) U.S. Cl. CPC H10K 59/8794; H05K 9/0067; H10K 2102/311; H10K 2102/351

(57) ABSTRACT

The present disclosure provides a heat dissipation film, a display module and a display apparatus. The heat dissipation film includes a metal layer, an adhesive layer, and a functional layer between the metal layer and the adhesive layer. The adhesive layer has a charge conduction property, and the functional layer has a stress buffering property. On at least one side of the heat dissipation film, an edge of at least one functional layer is retracted relative to an edge of the adhesive layer, such that after the heat dissipation film is bonded to a back film, the metal layer contacts the adhesive layer on the at least one side.

### CROSS REFERENCE TO RELATED APPLICATION(S)

This application claims priority to Chinese Patent Application No. 202410077514.0, filed on Jan. 18, 2024, the entire content of which is incorporated herein in its entirety by reference.

### TECHNICAL FIELD

The present disclosure pertains to a technical field of display, and relates to a heat dissipation film, a display module and a display apparatus.

### BACKGROUND

In recent years, flexible display modules have developed rapidly and have been widely used in various display products, such as curved screen mobile phones, curved screen TVs, and curved display screens. However, soon after the curved display products were launched on the market, low grayscale display abnormalities such as greenish and shiny colors appeared, which hinders their large-scale market promotion. Researchers have found that during the use of the display module, the surface of the protective layer (such as cover glass) may generate static electricity due to friction and other reasons, and the static electricity is conducted and accumulated in the back film. This causes an electrostatic field to be generated inside the display module, and affects the characteristics of transistors, which may lead to the above problem of low grayscale display abnormalities.

### SUMMARY

In a first aspect of the present disclosure, there is provided a heat dissipation film configured to be bonded to a back film of a display panel, and including a metal layer, an adhesive layer, and a functional layer between the metal layer and the adhesive layer, the adhesive layer has a charge conduction property, the functional layer has a stress buffering property; and on at least one side of the heat dissipation film, an edge of at least one functional layer is retracted relative to an edge of the adhesive layer, such that after the heat dissipation film is bonded to the back film, the metal layer contacts the adhesive layer on the at least one side In conjunction with the first aspect of the present disclosure, in some implementations, a plurality of functional layers are provided, the plurality of functional layers include a foam layer and a support layer arranged in stack, the foam layer is arranged on a side of the adhesive layer close to the metal layer, the support layer is arranged on a side of the foam layer away from the adhesive layer; and on at least one side of the heat dissipation film, an edge of the support layer and an edge of the metal layer are retracted relative to the edge of the adhesive layer.

In conjunction with the first aspect of the present disclosure, in some implementations, on at least one side of the heat dissipation film, along a direction perpendicular to a surface of the heat dissipation film, the edge of the support layer is flush with the edge of the metal layer, and an edge of the foam layer is flush with the edge of the adhesive layer.

In conjunction with the first aspect of the present disclosure, in some implementations, on at least one side of the heat dissipation film, an edge of the foam layer is retracted relative to the edge of the adhesive layer; a retracted distance of the edge of the support layer and the edge of the metal layer relative to the edge of the adhesive layer is a first distance, a retracted distance of the edge of the foam layer relative to the edge of the adhesive layer is a second distance, and the second distance is less than or equal to the first distance.

In conjunction with the first aspect of the present disclosure, in some implementations, the first distance is greater than 150 microns and less than or equal to 250 microns.

In conjunction with the first aspect of the present disclosure, in some implementations, the adhesive layer includes a first body portion and a first bending portion connected to the first body portion, the first body portion is parallel to the functional layer, the first bending portion is bent toward the metal layer relative to the first body portion and covers a side surface of the functional layer, and an end of the first bending portion away from the first body portion contacts the metal layer; or the metal layer includes a second body portion and a second bending portion connected to the second body portion, the second body portion is parallel to the functional layer, the second bending portion is bent toward the adhesive layer relative to the second body portion and covers a side surface of the functional layer, and an end of the second bending portion away from the second body portion contacts the adhesive layer.

In conjunction with the first aspect of the present disclosure, in some implementations, a resistance value of the adhesive layer is in a range of 104 to 105 ohms.

In conjunction with the first aspect of the present disclosure, in some implementations, a thickness of the adhesive layer is in a range of 25 to 35 microns along a direction perpendicular to a surface of the heat dissipation film.

In a second aspect of the present disclosure, there is provided a display module. The display module includes a display panel; a back film arranged on a backlight side of the display panel; and the heat dissipation film provided in the first aspect of the present disclosure, in which an adhesive layer of the heat dissipation film is bonded to a side of the back film away from the display panel, and on at least one side of the heat dissipation film, the adhesive layer of the heat dissipation film contacts a metal layer.

In conjunction with the second aspect of the present disclosure, in some implementations, the display panel has a curved side, at least one side of the heat dissipation film is a side directly opposite to the curved side, and the adhesive layer covers a side surface of a functional layer of the heat dissipation film and contacts the metal layer.

In conjunction with the second aspect of the present disclosure, in some implementations, the adhesive layer includes an overflow portion configured to cover the side surface of the functional layer and contact the metal layer; and the overflow portion is formed by squeezing the adhesive layer during a bonding process.

In conjunction with the second aspect of the present disclosure, in some implementations, the functional layer of the heat dissipation film includes a foam layer and a support layer arranged in stack; an edge of the support layer is retracted relative to an edge of the foam layer and an edge of the metal layer, and the overflow portion covers a side surface of the foam layer and a side surface of the support layer, and contacts the metal layer.

In conjunction with the second aspect of the present disclosure, in some implementations, the adhesive layer includes an overlapping portion, the overlapping portion is a portion exceeding edges of other film layers of the heat dissipation film, and the overlapping portion covers the side surface of the functional layer and contacts the metal layer.

In conjunction with the second aspect of the present disclosure, in some implementations, the functional layer of the heat dissipation film includes a foam layer and a support layer arranged in stack, an edge of the support layer exceeds an edge of the foam layer, an edge of the metal layer exceeds the edge of the support layer, and the overlapping portion covers a side surface of the foam layer and a side surface of the support layer, and contacts the metal layer.

In conjunction with the second aspect of the present disclosure, in some implementations, the at least one side of the heat dissipation film is any one or more sides of the heat dissipation film, the adhesive layer includes a first body portion and a first bending portion connected to the first body portion, the first body portion is parallel to the functional layer of the heat dissipation film, the first bending portion is bent toward the metal layer relative to the first body portion and covers a side surface of the functional layer, an end of the first bending portion away from the first body portion contacts the metal layer; the first body portion is bonded to a side of the back film away from the display panel.

In conjunction with the second aspect of the present disclosure, in some implementations, at least one side of the heat dissipation film is any one or more sides of the heat dissipation film, the metal layer includes a second body portion and a second bending portion connected to the second body portion, the second body portion is parallel to the functional layer connected thereto, the second bending portion is bent toward the adhesive layer relative to the second body portion and covers a side surface of the functional layer. The adhesive layer includes a first adhesive region and a second adhesive region, the first adhesive region is a region adhered to the functional layer, the second adhesive region is located outside the first adhesive region, one side of the second adhesive region is adhered to the back film, and the other side of the second adhesive region contacts an end of the second bending portion away from the second body portion.

In a third aspect, there is provided a display apparatus, including the display module provided in the second aspect above.

The above description is only an overview of the technical solutions provided by some embodiments of the present disclosure. In order to more clearly understand the technical means of the embodiments of the present disclosure so that they may be implemented in accordance with the contents of the specification, and in order to make the embodiments of the present disclosure more obvious and easier to understand, the specific implementations of the embodiments of the present disclosure will be illustrated below.

### BRIEF DESCRIPTION OF THE DRAWINGS

In order to more clearly illustrate the technical solutions in the present disclosure, the drawings required for describing the embodiments will be briefly introduced as follows. Obviously, the drawings described below are some embodiments of the present disclosure. Those of ordinary skills in the art may obtain other drawings based on these drawings without creative effort.

FIG. 1 shows a schematic structural diagram of an exemplary display module;

FIG. 2 shows a schematic structural diagram of a target side of a heat dissipation film according to some embodiments of the present disclosure;

FIG. 3 shows a schematic structural diagram of a target side of a heat dissipation film according to some other embodiments of the present disclosure;

FIG. 4 shows a schematic structural diagram of a target side of a heat dissipation film according to yet some other embodiments of the present disclosure;

FIG. 5 shows a schematic structural diagram of a target side of a heat dissipation film according to some further embodiments of the present disclosure;

FIG. 6 shows a schematic structural diagram of a target side of a heat dissipation film according to yet some further embodiments of the present disclosure;

FIG. 7 shows a schematic diagram of bonding the heat dissipation film shown in FIG. 2 to a back film;

FIG. 8 shows a schematic diagram of a local structure of a display module according to some embodiments of the present disclosure;

FIG. 9 shows a schematic plan diagram of a display panel according to some embodiments of the present disclosure;

FIG. 10 shows a micrograph of a display module using the heat dissipation film shown in FIG. 2;

FIG. 11 shows a schematic diagram of a local structure of a display module according to some other embodiments of the present disclosure;

FIG. 12 shows a schematic diagram of a local structure of a display module according to yet some other embodiments of the present disclosure;

FIG. 13 shows a schematic diagram of a local structure of a display module according to some further embodiments of the present disclosure; and

FIG. 14 shows a schematic structural diagram of a display apparatus according to some embodiments of the present disclosure.

### DETAILED DESCRIPTION OF EMBODIMENTS

Exemplary embodiments of the present disclosure will be described below in more detail with reference to the accompanying drawings. Although exemplary embodiments of the present disclosure are shown in the drawings, it should be understood that the present disclosure may be embodied in various forms and should not be limited to the embodiments set forth herein. Rather, these embodiments are provided to enable a more thorough understanding of the present disclosure and to fully convey the scope of the present disclosure to those skilled in the art.

It should be noted that the expression “plurality” used herein includes two or more than two. The expression “at least one” includes one or more than one. The word such as “comprise”, “include” or “contain” refers to that the element or item before this word includes the elements or items listed after this word and their equivalents, but other elements or objects are not excluded. Words such as “upper”, “lower”, “left” and “right” are only used to express relative position relationships. When an absolute position of the described object changes, the relative position relationship may also change accordingly.

The terms “parallel”, “vertical” and “equal” as used herein include the condition stated and conditions approximate to the condition stated, and the approximate conditions are within an acceptable deviation range as determined by those of ordinary skills in the art taking into account the measurement in question and the errors associated with the measurement of a particular quantity (i.e., the limitations of the measurement system). For example, “parallel” includes “absolute parallel” and “approximate parallel”, where an acceptable deviation range of “approximate parallel” may be, for example, a deviation within 5°. “Vertical” includes “absolute vertical” and “approximate vertical”, where an acceptable deviation range of “approximate vertical” may also be, for example, a deviation within 5°. “Equal” includes “absolute equal” and “approximate equal”, where an acceptable deviation range of “approximate equal” may be, for example, that a difference between two that are equal is less than or equal to 5% of either one.

It should be understood that in the exemplary embodiments of the present disclosure, when a layer or an element is referred to as being on another layer or a substrate, the layer or the element may be directly on another layer or the substrate, or there may be an

### Intermediate Layer Between the Layer or the Element and Another Layer or the Substrate.

FIG. 1 shows a schematic structural diagram of an exemplary display module. As shown in FIG. 1, the display module may include structures such as a display panel PNL, a back film BL and a heat dissipation film SL. The back film BL is arranged on a backlight side of the display panel PNL, and the heat dissipation film SL is bonded to a side of the back film BL away from the display panel PNL. Each organic film material of the display module such as an OLED mobile phone module is a polar material. For example, the base material of the back film SL, such as PET (Polyethylene Terephthalate), is a strong polar material, which has an electret effect, and works together with the power signal line Vss, resulting in a strong fringe electric field E of the product. Moreover, for a curved display product, after a 3D-lamination process of the display module is completed, an external film material of the display panel PNL, such as the back film BL, usually exceeds an edge of the display panel PNL. This increases the dielectric constant at the edge of the display module, and then increases the strength of the fringe electric field E, thereby pushing the charges in the base substrate of the display panel PNL toward the gate of the transistor, causing the channel of the transistor to be opened, and resulting in a brighter abnormal area in a low grayscale display. Due to the stable retention characteristics of the base material of the back film BL after polarization, the electric field will still exist even if the electrostatic charge Q on the surface of the cover glass CG is eliminated later.

In view of this, the inventors change the film structure of the heat dissipation film to release the charges accumulated in the back film, thereby reducing the electrostatic field in the display module and relieving the problem of low grayscale display abnormalities (e.g., shiny and greenish colors) of curved surface display products. Hereinafter, the heat dissipation film, the display module and the display apparatus provided by some embodiments of the present disclosure will be described in detail with reference to the accompanying drawings.

Some embodiments of the present disclosure provide a heat dissipation film. The heat dissipation film is used to be bonded to a back film of a display panel. In some implementations, the display panel may be a flexible display panel having at least one curved side. Taking an application in a curved screen mobile phone as an example, two opposite long sides of the display panel may be curved sides. The heat dissipation film may play a role of dissipating heat and buffering stress for the display panel. In some implementations, the heat dissipation film may be a super clean foam (SCF) composite film.

The heat dissipation film is of a multi-layer stacked structure. In some implementations, the heat dissipation film may include a metal layer, an adhesive layer, and a functional layer between the metal layer and the adhesive layer. The functional layer has a stress buffering property and may buffer stress and impact applied to the display panel from the outside. There may be one or more functional layers. During use, the heat dissipation film is bonded to a back film provided on a backlight side of the display panel through the adhesive layer. Since both the adhesive layer and the back film are made of flexible materials, it is beneficial to avoiding mold imprinting and ensuring the bonding quality.

On at least one side of the heat dissipation film, an edge of at least one functional layer is retracted relative to an edge of the adhesive layer, so that after the heat dissipation film is bonded to the back film, the metal layer contacts the adhesive layer on the at least one side. Since the heat dissipation film is bonded to the back film through the adhesive layer and the adhesive layer has a charge conduction property, the adhesive layer contacts the metal layer, so that electrostatic charges accumulated in the back film may be conducted to the metal layer, and the metal layer is grounded in the display apparatus, for example, it is connected to a product housing through a conductive structure. This may release the electrostatic static charges, thereby helping reduce the electrostatic field in the display module and relieve the problem of low grayscale display abnormalities of curved surface display products. Moreover, the dielectric constant of the functional layer of the heat dissipation film is usually relatively large, and retraction of at least one functional layer is beneficial to reducing the strength of the fringe electric field. Compared with manners such as coating a conductive liquid to achieve charge conduction and release, this does not require additional apparatuses and additional processes, and the cost is lower. Compared with the manner of directly contacting the metal layer of the heat dissipation film with the back film, this is beneficial to reducing mold imprinting and ensuring the bonding quality.

It should be noted that the “at least one side of the heat dissipation film” described above may be one side, two sides, three sides or four sides of the heat dissipation film, and this may be set according to the needs of the actual product. In some implementations, the “at least one side” described above may also be determined according to the shape of the adapted display panel and the number of the curved sides. For example, the display panel adapted to the heat dissipation film is square, including a first side, a second side, a third side and a fourth side adjacent to one another in sequence, and the first side and the third side are oppositely arranged and are both curved sides of the display panel. Correspondingly, the heat dissipation film is also a square film, “at least one side” described above is two sides, and the two sides are opposite to each other and respectively adapted to the first side and the third side. For convenience of illustration, “at least one side of the heat dissipation film” described above will be referred to as a target side of the heat dissipation film hereinafter.

In some implementations, the heat dissipation film is used for a curved screen display product, and the display panel has curved sides. The target side described above may be a side of the heat dissipation film that is directly opposite to the curved side. During a 3D lamination process of the display module, the target side of the heat dissipation film is bent along with the curved side of the display panel. After the 3D lamination process of the display module is completed, the adhesive layer of the heat dissipation film contacts the metal layer on the target side, that is, the electrostatic charges may be conducted between the two.

In some implementations, the functional layer may include a foam layer, and the foam layer is arranged on a side of the adhesive layer close to the metal layer. For example, the foam layer may be made of polyurethane (PU) or other suitable materials. In some implementations, the foam layer may have a resistance value of approximately 1010 ohms and a thickness of approximately 80 microns.

In some implementations, a plurality of functional layers are provided between the adhesive layer and the metal layer. In addition to the foam layer, the functional layers may also include a support layer arranged on a side of the foam layer close to the metal layer and playing a role of providing support and impact resistance. In some implementations, the support layer may be black to enhance the overall black effect of the product. In some implementations, the support layer may be a black PI (polyimide) layer or other applicable support layer materials. In some implementations, the support layer may have a resistance value of approximately 1010 ohms and a thickness of approximately 40 microns. Certainly, in other implementations, other functional layers may be provided between the adhesive layer and the metal layer. This may be set according to actual needs, and the present disclosure does not impose any restrictions on this.

In some implementations, the adhesive layer may be made of an embossing (EMBO) glue or other applicable adhesive materials. The embossing glue may reduce bubbles generated during adhesion of the foam layer and the display panel, thereby enhancing the connection strength between the heat dissipation film and the display panel. Certainly, an unused heat dissipation film may further include a protective film (also referred to as a bottom protective film), and the protective film is bonded to a side of the adhesive layer away from the metal layer to protect the adhesive layer. During use, the protective film must be peeled off first and then the heat dissipation film is bonded to the back film of the display panel.

It may be understood that the adhesive layer of a traditional heat dissipation film is usually made of a relatively high impedance material with a resistance value of about 109 ohms, which may basically be considered as insulating and does not have an electrostatic charge conduction property. In some implementations, the adhesive layer may be made of a material with a relatively low impedance and having an adhesive property. For example, an embossing glue material with a relatively low impedance (such as having a resistance value of approximately 104 ohms) may be used. Alternatively, a low impedance adhesive layer may be formed by adding conductive materials such as carbon nanotubes or metal nanoparticles to the adhesive layer material of a traditional heat dissipation film, so that the adhesive layer has a charge conduction property. In some implementations, the resistance value of the adhesive layer may be 104 to 105 ohms, for example, it may be 104 ohms or 105 ohms.

In some implementations, the thickness of the adhesive layer along a direction perpendicular to a surface of the heat dissipation film may be 25 to 35 microns, for example, 25 microns, 30 microns, or 35 microns. The thickness of the adhesive layer of a traditional heat dissipation film is about 50 to 70 microns. By reducing the thickness of the adhesive layer, the impedance of the adhesive layer may be further reduced, thereby improving the charge conduction performance of the adhesive layer, and better conducting the electrostatic charges accumulated in the back film to the metal layer for release.

The metal layer has a heat dissipation property and an electrical conductivity property. In some implementations, the material of the metal layer may include copper. Certainly, in other implementations, the metal layer may also be made of other applicable metal materials such as aluminum, and the present disclosure does not impose any restrictions on this.

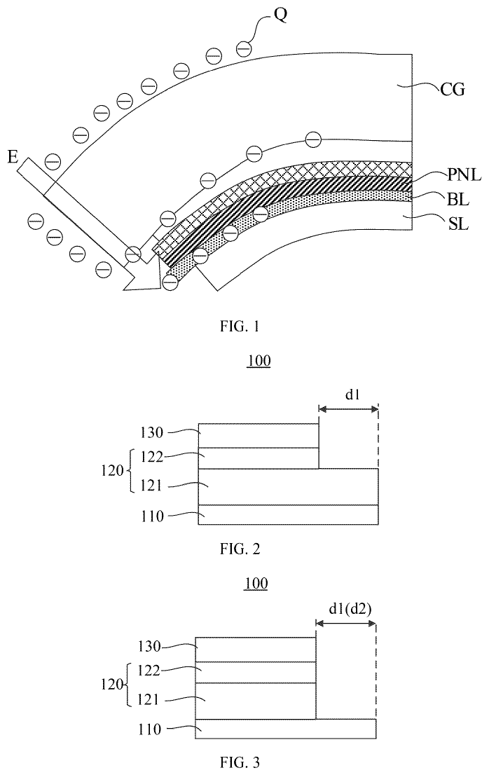

FIG. 2 shows a schematic structural diagram of a target side of a heat dissipation film according to some embodiments of the present disclosure. As shown in FIG. 2, the heat dissipation film 100 may include an adhesive layer 110, a foam layer 121, a support layer 122, and a metal layer 130, which are stacked in sequence. The foam layer 121 and the support layer 122 are both the functional layers 120 of the heat dissipation film 100. The adhesive layer 110 is located on a side of the foam layer 121 away from the metal layer 130, and the support layer 122 is located on a side of the foam layer 121 close to the metal layer 130. In some implementations, the metal layer 130 and the support layer 122 may be adhered using a pressure sensitive adhesive (PSA).

In some implementations, on the target side of the heat dissipation film 100, an edge of the support layer 122 and an edge of the metal layer 130 are retracted relative to an edge of the adhesive layer 110, so that the edge of the adhesive layer 110 exceeds the edge of the support layer 122, as shown in FIG. 2.

During the 3D curved surface lamination process, the target side of the heat dissipation film 100 is bent with the curved side of the display panel 200. The heat dissipation film 100 is subjected to a pressure applied by the back film 101, causing the film layers to be misaligned. Moreover, the adhesive layer 110 is a glue layer having a certain fluidity, and is prone to glue overflow when subjected to pressure. According to the structure of the heat dissipation film 100 shown in FIG. 2, the misaligned layers of the film layers in the heat dissipation layer and the glue overflow of the adhesive layer 110 under the squeezing action of the back film 101 and the foam layer 121 may be cleverly used to achieve the overlap between the adhesive layer 110 and the metal layer 130.

For convenience of illustration, a retracted distance of the support layer 122 and the metal layer 130 relative to the adhesive layer 110 in FIG. 2 is referred to as a first distance d1. The first distance d1 may be set according to the actual needs of the product, as long as the adhesive layer 110 and the metal layer 130 may overlap through the glue overflow of the adhesive layer 110 and the misaligned layers of the film layers in the heat dissipation film 100 during the 3D lamination process. The present disclosure does not impose any restrictions on this. After DOE (design of experiment) verification, in some implementations, the first distance dl may be greater than 150 microns and less than or equal to 250 microns, for example, it may be 160 microns, 180 microns, 200 microns, 220 microns or 250 microns.

In some implementations, as shown in FIG. 2, on the target side of the heat dissipation film 100, along the direction perpendicular to the surface of the heat dissipation film 100, the edge of the support layer 122 is flush with the edge of the metal layer 130 to facilitate processing.

In some implementations, as shown in FIG. 2, on the target side of the heat dissipation film 100, the edge of the foam layer 121 is flush with the edge of the adhesive layer 110, so that during lamination, the back film 101 and the foam layer 121 may squeeze the adhesive layer 110 from two opposite sides. This allows the adhesive layer 110 to achieve a more ideal overflow effect, which is sufficient for the adhesive layer 100 to be overlapped with the metal layer 130. In some other implementations, on the target side of the heat dissipation film 100, the edge of the foam layer 121 is also retracted relative to the edge of the adhesive layer 110. This may reduce the obstruction between the edge of the adhesive layer 110 and the metal layer 130, which is beneficial for a portion of the edge of the adhesive layer 110 protruding from the functional layer 120 to be close to the metal layer 130, and overlapped with the metal layer 130.

A retracted distance of the edge of the foam layer 121 relative to the edge of the adhesive layer 110 is a second distance d2. In some implementations, the second distance d2 may be less than or equal to the first distance d1. That is, the edge of the foam layer 121 may be flush with the edge of the support layer 122 and the edge of the metal layer 130, or may be located between the edge of the support layer 122 and the edge of the adhesive layer 110.

FIG. 3 shows a schematic structural diagram of a target side of a heat dissipation film 100 according to some other embodiments of the present disclosure. As shown in FIG. 3, on the target side of the heat dissipation film 100, along the direction perpendicular to the surface of the heat dissipation film 100, the edge of the foam layer 121, the edge of the support layer 122, and the edge of the metal layer 130 are flush, that is, the second distance d2 is equal to the first distance d1. In this way, the portion of the adhesive layer 110 that exceeds the edge of the metal layer 130 is basically free of obstruction on the side away from the back film 101 and may be used as an overlapping portion 114 to be overlapped with the metal layer 130. During the 3D lamination process of the display module 10, the film layers on the target side of the heat dissipation film 100 are misaligned due to bending, so that the above overlapping portion 114 of the adhesive layer 110 is close to the edge of the metal layer 130. On this basis, due to the glue overflow caused by pressing the adhesive layer 110, the overlapping of the adhesive layer 110 with the metal layer 130 may be achieved.

FIG. 4 shows a schematic structural diagram of a target side of a heat dissipation film 100 according to yet some other embodiments of the present disclosure. As shown in FIG. 4, on the target side of the heat dissipation film 100, the edge of the foam layer 121 is retracted relative to the edge of the adhesive layer 110, and the support layer 122 is flush with the edge of the metal layer 130 and retracted relative to the edge of the foam layer 121, that is, the above second distance d2 may also be less than the first distance d1.

In some other implementations, the adhesive layer 110 or the metal layer 130 may be designed with a special shape on at least one side of the heat dissipation film 100, so that the adhesive layer 110 and the metal layer 130 overlap in the heat dissipation film 100 before being bonded. This is beneficial to ensuring the overlapping reliability between the two.

FIG. 5 shows a schematic structural diagram of a target side of a heat dissipation film 100 according to some further embodiments of the present disclosure. As shown in FIG. 5, the adhesive layer 110 includes a first body portion 111 and a first bending portion 112 connected to the first body portion 111. The first body portion 111 is parallel to the functional layer 120, such as the foam layer 121 described above. The first bending portion 112 is bent toward the metal layer 130 relative to the first body portion 111, and covers side surfaces of various functional layers 120. An end of the first bending portion 112 away from the first body portion 111 contacts the metal layer 130. By designing the adhesive layer 110 to be of a special shape, the adhesive layer 110 and the metal layer 130 overlap to provide a release path for electrostatic charges.

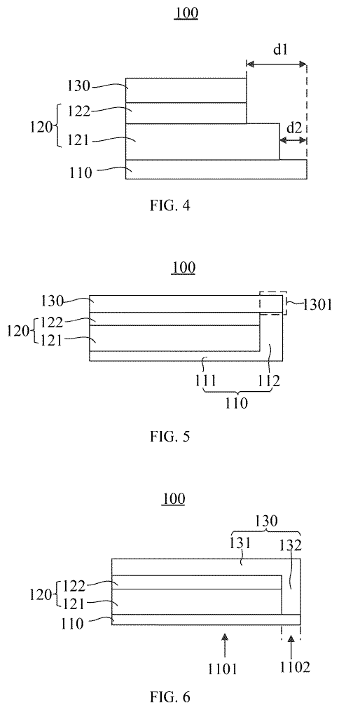

FIG. 6 shows a schematic structural diagram of a target side of a heat dissipation film 100 according to yet some further embodiments of the present disclosure. As shown in FIG. 6, the metal layer 130 includes a second body portion 131 and a second bending portion 132 connected to the second body portion 131. The second body portion 131 is parallel to the functional layer 120, such as the support layer 122 described above. The second bending portion 132 is bent toward the adhesive layer 110 relative to the second body portion 131, and covers the side surfaces of various functional layers 120. An end of the second bending portion 132 away from the second body portion 131 contacts the adhesive layer 110. By designing the metal layer 130 to be of a special shape, the adhesive layer 110 and the metal layer 130 overlap to provide a release path for the electrostatic charges.

As shown in FIG. 5 and FIG. 6, edges of various functional layers 120 (such as the foam layer 121 and the support layer 122) located between the adhesive layer 110 and the metal layer 130 may be flush, and retracted relative to the metal layer 130 and the adhesive layer 110. In the embodiment corresponding to FIG. 5, the metal layer 130 has a protruding portion 1301 protruding from the edge of the functional layer 120, and the first bending portion 112 of the adhesive layer 110 covers the side surfaces of various functional layers 120 and contacts a side of the protruding portion 1301 facing the adhesive layer 110. In the embodiment corresponding to FIG. 6, the adhesive layer 110 may include a first adhesive region 1101 and a second adhesive region 1102. The first adhesive region 1101 is a region adhered to the functional layer 120, and the second adhesive region 1102 is a region outside the first adhesive region 1101. One side of the second adhesive region 1102 is configured to be adhered to the back film 101, and the other side contacts an end of the second bending portion 132 away from the second body portion 131.

The first bending portion 112 and the second adhesive region 1102 described above have an adhesive property. The first bending portion 112 contacts the protruding portion 1301, or an end of the second bending portion 132 away from the second body portion 131 contacts the second adhesive region 1102, so as to achieve adhesion between the two and ensure the stability of the charge release path. In some implementations, a conductive glue may be coated or a conductive cloth may be bonded at the adhesion position to further improve the stability of the charge release path.

In some implementations, the size of the heat dissipation film 100 is slightly less than that of the back film 101. FIG. 7 shows a schematic diagram of bonding the heat dissipation film 100 shown in FIG. 2 to a back film 101. As shown in FIG. 7, before the 3D lamination process, the edge of the adhesive layer 110 is retracted relative to the edge of the back film 101, and a retracted distance D may be greater than 0 and less than 300 microns, for example, it may be 100 microns, 200 microns or 250 microns. The less the retracted distance D of the heat dissipation film 100 relative to the back film 101 is, the easier it is for various film layers of the heat dissipation film 100 to contact one another during the 3D lamination process of the display module 10.

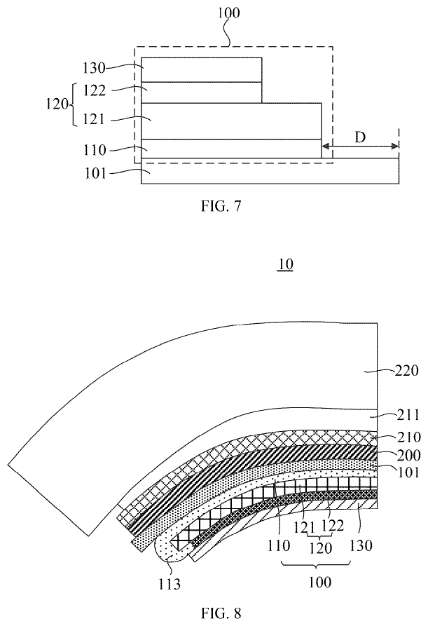

FIG. 8 shows a schematic diagram of a local structure of a display module 10 according to some embodiments of the present disclosure. As shown in FIG. 8, some embodiments of the present disclosure further provide a display module 10. The display module 10 includes a display panel 200, a back film 101, and the heat dissipation film 100 provided in any of the above embodiments.

It should be noted that, in addition to the above structures, the display module 10 may further include other materials such as a protective layer 220 and a polarizer (POL) 210 shown in FIG. 8. This may be determined according to the needs of the actual product. The protective layer 220 is arranged on a light exiting side of the display panel 200, and the polarizer 210 may be arranged between the display panel 200 and the protective layer 220. In some implementations, the protective layer 220 may be a cover glass, and the cover glass may be adhered to a side of the polarizer 210 away from the display panel 200 through an optically clear adhesive (OCA) 211. Certainly, in other implementations, the protective layer 220 may also be made of other materials such as a transparent resin material and PET (polyethylene terephthalate), and the present disclosure does not impose any limits on this. Taking cover glass as an example, when applied to curved surface display products, the cover glass is a 3D cover glass. At least one side of the cover glass is bent, and various layers of the display module 10 are bonded together through the 3D lamination process.

FIG. 9 shows a schematic plan diagram of a display panel 200 according to some embodiments of the present disclosure. As shown in FIG. 9, the display panel 200 may include a display region AA and a non-display region SA arranged at least on one side of the display region AA. The display region AA includes a plurality of pixels arranged in an array. Each pixel includes a plurality of sub-pixels. Each sub-pixel may display a single color, for example, a red sub-pixel displays red, a green sub-pixel displays green, and a blue sub-pixel displays blue. The brightnesses (grayscales) of sub-pixels of different colors in each pixel may be adjusted, and multiple colors may be displayed through color combination and superposition, thereby achieving a full-color display of the display panel 200.

In some implementations, the plurality of sub-pixels described above include three sub-pixels, i.e., a first sub-pixel, a second sub-pixel, and a third sub-pixel, and different sub-pixels emit lights of different colors. For example, the first sub-pixel may be a red sub-pixel, the second sub-pixel may be a green sub-pixel, and the third sub-pixel may be a blue sub-pixel. Certainly, in other implementations, each pixel may also include other numbers of sub-pixels, such as four sub-pixels. This may be set according to actual application scenarios, and the present disclosure does not impose any restrictions on this.

In some implementations, the display panel 200 is a flexible display panel, such as an organic light emitting diode (OLED) display panel or a quantum dot organic light emitting diode (QLED). This is specifically set according to the needs of the actual application scenario, and the present disclosure does not impose any restrictions on this.

In some implementations, the display panel 200 may include: a backplane and a display structure layer stacked on the backplane. In some implementations, a side of the backplane away from the display structure layer may be the backlight side of the display panel 200, and a side of the display structure layer away from the backplane may be the light exiting side of the display panel 200.

In some implementations, the backplane may include a base substrate and a pixel driving layer arranged on the base substrate. Certainly, the backplane may also include other structures, and this is specifically designed according to the needs of the actual product. For example, the backplane may also include a fingerprint identification circuit, and the present disclosure does not impose any restrictions on this.

In some implementations, the base substrate may be a flexible substrate. The flexible substrate may include, for example, a PET substrate, a PEN (polyethylene naphthalate two formic acid glycol ester) substrate, or a PI substrate. It should be noted that the base substrate may be a single-layer structure or a multi-layer structure. For example, the base substrate may include at least one flexible substrate and at least one buffer layer, which are alternately stacked.

The pixel driving layer is used to form a plurality of pixel driving circuits arranged in an array. The pixel driving circuit may include electronic components such as a plurality of transistors and capacitors. For example, each pixel driving circuit may include three transistors and one capacitor to form a 3T1C (i.e., one driving transistor, two switching transistors and one capacitor). It may also include more than three transistors and at least one capacitor, such as 4T1C (i.e., one driving transistor, three switching transistors and one capacitor), 5T1C (i.e., one driving transistor, four switching transistors and one capacitor) or 7T1C (i.e., one driving transistor, six switching transistors and one capacitor). The transistor may be a thin film transistor (TFT), a metal oxide semiconductor (MOS) transistor or other switching devices with the same characteristics.

It may be understood that the transistor may include a control electrode, a first electrode and a second electrode. The control electrode is a gate of the transistor, the first electrode is one of a source and a drain of the transistor, and the second electrode is the other of the source and the drain of the transistor. Since a source and a drain of a transistor may be symmetrical in structure, there may be no difference in structure between the source and the drain. Therefore, the source of the transistor is referred to as the first electrode, and may also be referred to as the second electrode.

In some implementations, the pixel driving layer may include an active layer, a first gate metal layer (Gate1), a second gate metal layer (Gate2), a first metal wiring layer (SD1), and a second metal wiring layer (SD2), and these film layers are configured to form transistors, capacitors, and a plurality of signal lines for pixel driving in the pixel driving circuit. For example, the plurality of signal lines may include power signal lines, data signal lines, reset signal lines, scan signal lines, enable signal lines, and initialization signal lines. Reference may be made to relevant technologies for details, which will not be described in detail here. The pixel driving layer may further include insulating layers separating these film layers. It should be noted that the film layers of the pixel driving layer listed above are for illustration only. In other implementations, the pixel driving layer may also include more or fewer film layers. For example, it may also include more metal wiring layers. This is specifically set according to the actual product needs, and the present disclosure does not impose any restrictions on this.

In some implementations, the display structure layer may include a light emitting device layer and an encapsulation layer. The light emitting device layer is stacked on a side of the pixel driving layer away from the base substrate. The light emitting device layer may include a pixel defining layer and a plurality of light emitting devices. The pixel defining layer has a plurality of pixel openings, and one pixel opening defines a position of one light emitting device. For example, the light emitting device may be an OLED light emitting device or a QLED light emitting device.

Taking an OLED light emitting device as an example, along a direction away from the base substrate, the light emitting device may include a first electrode, a light emitting layer, and a second electrode stacked in sequence. Certainly, the light emitting device may also include at least one of a hole injection layer, a hole transport layer, and an electron blocking layer arranged between the first electrode and the light emitting layer, and at least one of an electron injection layer, an electron transport layer, and a hole blocking layer arranged between the second electrode and the light emitting layer. This is specifically set according to the actual needs, and the present disclosure does not impose any restrictions on this.

In some implementations, the first electrode may be an anode and the second electrode may be a cathode. The structure of the anode may be a composite structure formed by sequentially stacking a transparent conductive oxide thin film, a metal thin film, a transparent conductive oxide thin film. The transparent conductive oxide thin film may be made of any one of ITO (indium tin oxide) and IZO (indium zinc oxide), and the metal thin film may be made of any one of gold (Au), silver (Ag), nickel (Ni) and platinum (Pt). For another example, the structure of the anode may also be a single-layer structure, and the material of the single-layer structure may be any one of ITO, IZO, Au, Ag, Ni, and Pt.

Each pixel opening exposes a portion of the anode of the corresponding light emitting device, and at least a portion of the light emitting layer is located within the corresponding pixel opening and is electrically connected with the corresponding anode.

For example, the cathodes of various light emitting devices may be electrically connected to one another to form an integrated structure. For example, the material of the cathode may be any one of aluminum (Al), silver (Ag), and magnesium (Mg), or any one of a magnesium silver alloy and an aluminum lithium alloy.

The encapsulation layer is arranged on a side of the light emitting device layer away from the base substrate to protect the light emitting device. In some implementations, the display panel 200 may include a first inorganic encapsulation layer, an organic encapsulation layer, and a second inorganic encapsulation layer. For example, the first inorganic encapsulation layer and the second inorganic encapsulation layer may be made of inorganic materials such as nitride, oxide, oxynitride, nitrate, carbide or any combination thereof, and the preparation process may adopt a chemical vapor deposition (CVD) process, such as a plasma enhanced chemical vapor deposition (PECVD) process. For example, an organic insulating layer may be made of materials such as acrylic fiber, hexamethyldisiloxane, polyacrylate, polycarbonate, and polystyrene, and the preparation process may be an ink jet printing (IJP) process. Certainly, in other examples, other encapsulation manners may also be used, such as inorganic thin film encapsulation, and the present disclosure does not impose any restrictions on this.

In some implementations, the display structure layer may further include a color filter layer that may be arranged on a side of the encapsulation layer away from the base substrate. In some implementations, the color filter layer may include a first color filter unit, a second color filter unit, and a third color filter unit. The first color filter unit, the second color filter unit and the third color filter unit are color filter units of different colors. The first color filter unit, the second color filter unit, and the third color filter unit may have different thicknesses, or the same thickness, or two of them may have the same thickness and the other one may have a different thickness. The present disclosure does not impose any restrictions on this.

In some implementations, adjacent color filter units of the color filter layer do not overlap each other, and the color filter layer also includes a black matrix arranged between adjacent color filter units to absorb ambient light, reduce ambient light reflection of the display panel 200, and achieve a dark state when the screen is turned off. Certainly, in other implementations, the first color filter unit and the second color filter unit may have a first overlapping area, the second color filter unit and the third color filter unit may have a second overlapping area, and the third color filter unit and the first color filter unit may have a third overlapping area. When two filter units of different colors overlap, the overlapping area has a low light transmittance, and therefore, it may be used as a black matrix. In this way, the first overlapping area, the second overlapping area and the third overlapping area of the display panel 200 may all be used as black matrices to achieve the light shading effect, without the need to provide an additional black matrix.

In some implementations, the first color filter unit is a red color filter unit, the second color filter unit is a green color filter unit, and the third color filter unit is a blue color filter unit.

In some implementations, the display panel 200 may further include a touch layer for implementing a touch function. In some implementations, the touch layer may be arranged between the encapsulation layer and the color filter layer to achieve an in-screen touch structure, which is beneficial to reducing the thickness of the display panel 200. Certainly, in other implementations, the touch layer may also be arranged at other positions of the display panel 200, and the present disclosure does not impose any restrictions on this.

The back film 101 is arranged on the backlight side of the display panel 200, for example, on a side of the base substrate away from the pixel driving layer. The adhesive layer 110 of the heat dissipation film 100 is bonded to the side of the back film 101 away from the display panel 200. On at least one side of the heat dissipation film 100, i.e., the target side of the heat dissipation film 100 described above, the adhesive layer 110 of the heat dissipation film 100 contacts the metal layer 130.

For the heat dissipation films 100 provided in different embodiments described above, the contact manners between the adhesive layer 110 and the metal layer 130 are slightly different. In some implementations, the display panel 200 has curved sides, and the target sides of the heat dissipation film 100 described above are sides directly opposite to the curved sides. For example, the first side 201 and the third side 202 of the display panel 200 in FIG. 9 are curved sides. Then, the target sides of the heat dissipation film 100 include a side directly opposite to the first side 201 and a side directly opposite to the third side 202. On the target side of the heat dissipation film 100, the adhesive layer 110 covers the side surfaces of various functional layers 120 of the heat dissipation film 100 and contacts the metal layer 130. It should be noted that, for the heat dissipation films 100 provided in the embodiments respectively corresponding to FIG. 2, FIG. 3 and FIG. 4, before the 3D lamination process, the adhesive layer 110 and the metal layer 130 are in a non-contact state, and the pressure received when the bent side of the display panel 200 is bent during lamination is cleverly used to achieve contact between the adhesive layer 110 and the metal layer 130 on the target side.

FIG. 8 shows a display module 10 using the heat dissipation film 100 shown in FIG. 2. As shown in FIG. 8, the adhesive layer 110 has an overflow portion 113. The overflow portion 113 covers the side surfaces of various functional layers 120 and contacts the metal layer 130. The overflow portion 113 is formed when the adhesive layer 110 is squeezed during the bonding process. The functional layers 120 located between the adhesive layer 110 and the metal layer 130 include a foam layer 121 and a support layer 122 arranged in stack. Before lamination, on the target side of the heat dissipation film 100, the metal layer 130 of the heat dissipation film 100 is flush with the support layer 122, the foam layer 121 is flush with the adhesive layer 110, and the support layer 122 and the metal layer 130 are retracted relative to the adhesive layer 110. During lamination, the target side of the heat dissipation film is bent along with the curved side of the display panel 200, and the adhesive layer 110 is squeezed by the back film 101 and the foam layer 121 and overflows from the edge, and is close to the metal layer 130 due to bending, thereby achieving contact with the metal layer 130.

In addition, during the 3D curved surface lamination process, the target side of the heat dissipation film 100 is bent with the curved side of the display panel 200, which may cause the film layers of the heat dissipation film 100 to be misaligned on the target side. For example, when the heat dissipation film 100 shown in FIG. 2 is used, after the target side is bent, the edge of the support layer 122 is retracted relative to the edge of the foam layer 121 and the edge of the metal layer 130, as shown in FIG. 8. It should be noted that before lamination, the support layer 122 and the metal layer 130 of the heat dissipation film 100 are flush on the target side, as shown in FIG. 2. During lamination, the target side of the heat dissipation film 100 is bent with the curved side of the display panel 200, and the support layer 122 and the metal layer 130 that are originally flush are misaligned, so that the edge of the metal layer 130 exceeds the edge of the support layer 122, making it easier to contact the overflow portion 113 of the adhesive layer 110.

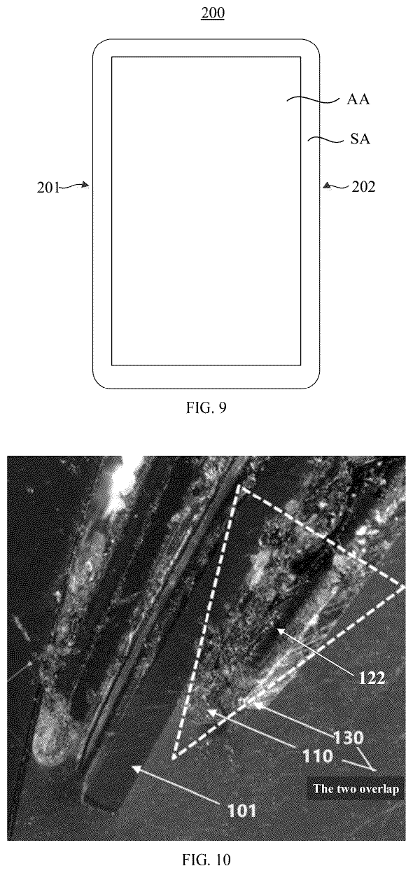

FIG. 10 shows a micrograph of a display module 10 using the heat dissipation film 100 shown in FIG. 2. As shown in FIG. 10, after lamination, on the target side of the heat dissipation film 100, the adhesive layer 110 is squeezed and overflows from the edge, thereby overlapping with the metal layer 130 exceeding the edge of the support layer 122.

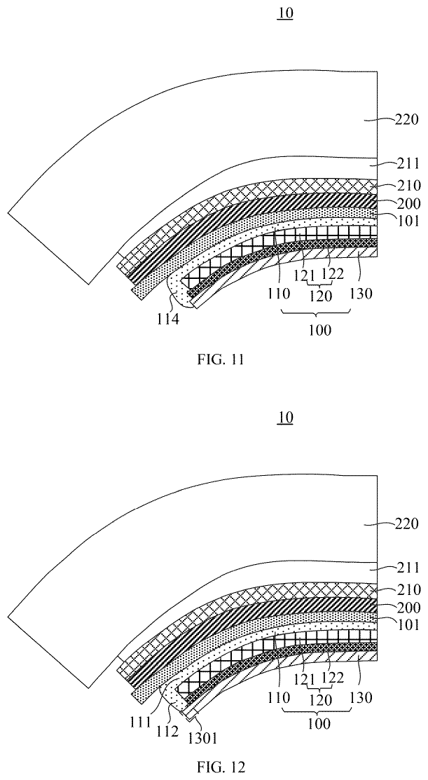

FIG. 11 shows a schematic diagram of a local structure of a display module 10 according to some other embodiments of the present disclosure. The display module 10 shown in FIG. 11 uses the heat dissipation film 100 shown in FIG. 3. Since the foam layer 121, the support layer 122 and the metal layer 130 in the heat dissipation film 100 shown in FIG. 3 are all retracted relative to the adhesive layer 110 on the target side, the adhesive layer 110 has an overlapping portion 114 on the target side, such as a portion exceeding edges of other film layers of the heat dissipation film 100 in FIG. 3. As shown in FIG. 11, the overlapping portion 114 of the adhesive layer 110 covers the side surfaces of various functional layers 120 and contacts the metal layer 130. It should be noted that before bonding, the foam layer 121, the support layer 122 and the metal layer 130 of the heat dissipation film 100 are flush, as shown in FIG. 3. After lamination, since the target side of the heat dissipation film 100 is bent with the curved side of the display panel 200, the foam layer 121, the support layer 122 and the metal layer 130 that are originally flush are misaligned on the target side, so that the edge of the support layer 122 slightly exceeds the edge of the foam layer 121, and the edge of the metal layer 130 slightly exceeds the edge of the support layer 122, thereby further facilitating overlapping of the overlapping portion 114 of the adhesive layer 110 with the metal layer 130.

In some implementations, in addition to the overlapping portion 114, the adhesive layer 110 may also overflow due to squeezing during the 3D lamination process. Through the reserved overlapping portion 114 and the overflow portion, the contact between the adhesive layer 110 and the metal layer 130 may be effectively achieved.

In some other implementations, the target side of the heat dissipation film 100 may include any one or more sides of the heat dissipation film 100, and the adhesive layer 110 of the heat dissipation film 100 and the metal layer 130 are in contact on at least one side of the heat dissipation film 100, without relying on the pressure applied on the side of the heat dissipation film 100 when it is bent with the curved side of the display panel 200 during lamination. In some implementations, in order to better release the electrostatic charges accumulated in the curved side of the back film 101, the target side of the heat dissipation film 100 may include a side directly opposite to the curved side.

FIG. 12 shows a schematic diagram of a local structure of a display module 10 according to yet some other embodiments of the present disclosure. The display module 10 shown in FIG. 12 uses the heat dissipation film 100 shown in FIG. 5. As shown in FIG. 12, the target side of the heat dissipation film 100 is the side directly opposite to the curved side of the display panel 200, and after lamination, the target side is in a curved state shown in FIG. 12. The first body portion 111 of the adhesive layer 110 is bonded to the side of the back film 101 away from the display panel 200, and the first bending portion 112 covers the side surfaces of various functional layers 120 of the heat dissipation film 100 and contacts the protruding portion 1301 of the metal layer 130, thereby forming an electrostatic charge conduction path from the back film 101 to the metal layer 130. The electrostatic charges accumulated in the back film 101 may be first transferred to the first body portion 111 of the adhesive layer 110, then transferred to the metal layer 130 through the first bending portion 112 of the adhesive layer 110, and finally released.

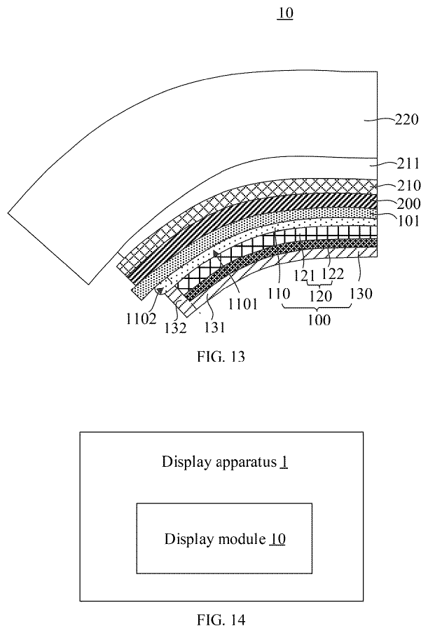

FIG. 13 shows a schematic diagram of a local structure of a display module 10 according to some further embodiments of the present disclosure. The display module 10 shown in FIG. 13 uses the heat dissipation film 100 shown in FIG. 6. As shown in FIG. 13, the target side of the heat dissipation film 100 is the side directly opposite to the curved side of the display panel 200, and after lamination, the target side is in a curved state as shown in FIG. 13. The adhesive layer 110 of the heat dissipation film 100 includes a first adhesive region 1101 and a second adhesive region 1102. The first adhesive region 1101 is a region adhered to the functional layer 120 of the heat dissipation film 100, that is, one side of the first adhesive region 1101 is adhered to the back film 101, and the other side is adhered to the functional layer 120 close to the adhesive layer 110. The second adhesive region 1102 is located outside the first adhesive region 1101. One side of the second adhesive region 1102 is adhered to the back film 101, and the other side contacts the second bending portion 132 of the metal layer 130. The second bending portion 132 of the metal layer 130 covers the side surfaces of the support layer 122 and the foam layer 121, and the end of the second bending portion 132 away from the second body portion 131 contacts the second adhesive region 1102, thereby forming an electrostatic charge conduction path from the back film 101 to the metal layer 130.

FIG. 14 shows a schematic structural diagram of a display apparatus 1 according to some embodiments of the present disclosure. As shown in FIG. 14, some embodiments of the present disclosure provide a display apparatus 1. The display apparatus 1 includes the display module 10 provided in any one of the above embodiments. In some implementations, the display apparatus 1 may be a curved screen display product, for example, it may be a product or component with a display function, such as a monitor, a television, a tablet computer, a laptop computer, a mobile phone, a digital photo frame or a navigator. Certainly, the display apparatus 1 provided by the embodiments of the present disclosure is not limited to the types listed above.

In the heat dissipation film, the display module and the display apparatus provided by some embodiments of the present disclosure, the adhesive layer having a charge conduction property is provided, and on at least one side of the heat dissipation film, the edge of at least one functional layer between the adhesive layer and the metal layer is retracted relative to the edge of the adhesive layer, so that after the heat dissipation film is bonded to the back film, the metal layer contacts the adhesive layer on at least one side of the heat dissipation film. In this way, the electrostatic charges accumulated in the back film are conducted to the metal layer through the adhesive layer and released, thereby effectively reducing the accumulation of the electrostatic charges in the back film, lowering the electrostatic field generated inside the display module, and helping relieve the problem of low grayscale display abnormalities of curved display products.

It should be noted that the drawings of the embodiments of the present disclosure only involve structures related to the embodiments of the present disclosure, and reference may be made to general designs for other structures. In case of no conflict, the embodiments of the present disclosure and the features therein may be combined with one another to form new embodiments.

Although some embodiments of the present disclosure have been described, those skilled in the art may make further changes and modifications to these embodiments once they know the basic inventive concepts. Therefore, it is intended that the appended claims may be interpreted as including the preferred embodiments and all changes and modifications that fall within the scope of the present disclosure.

1. A heat dissipation film configured to be bonded to a back film of a display panel, wherein the heat dissipation film comprises a metal layer, an adhesive layer, and a functional layer between the metal layer and the adhesive layer, the adhesive layer has a charge conduction property, and the functional layer has a stress buffering property; and
wherein on at least one side of the heat dissipation film, an edge of at least one functional layer is retracted relative to an edge of the adhesive layer, such that after the heat dissipation film is bonded to the back film, the metal layer contacts the adhesive layer on the at least one side.

2. The heat dissipation film according to claim 1, wherein a plurality of functional layers are provided, the plurality of functional layers comprise a foam layer and a support layer arranged in stack, the foam layer is arranged on a side of the adhesive layer close to the metal layer, and the support layer is arranged on a side of the foam layer away from the adhesive layer; and
wherein on at least one side of the heat dissipation film, an edge of the support layer and an edge of the metal layer are retracted relative to the edge of the adhesive layer.

3. The heat dissipation film according to claim 2, wherein on at least one side of the heat dissipation film, along a direction perpendicular to a surface of the heat dissipation film, the edge of the support layer is flush with the edge of the metal layer, and an edge of the foam layer is flush with the edge of the adhesive layer.

4. The heat dissipation film according to claim 2, wherein on at least one side of the heat dissipation film, an edge of the foam layer is retracted relative to the edge of the adhesive layer; a retracted distance of the edge of the support layer and the edge of the metal layer relative to the edge of the adhesive layer is a first distance, a retracted distance of the edge of the foam layer relative to the edge of the adhesive layer is a second distance, and the second distance is less than or equal to the first distance.

5. The heat dissipation film according to claim 4, wherein the first distance is greater than 150 microns and less than or equal to 250 microns.

6. The heat dissipation film according to claim 1, wherein the adhesive layer comprises: a first body portion and a first bending portion connected to the first body portion, the first body portion is parallel to the functional layer, the first bending portion is bent toward the metal layer relative to the first body portion and covers a side surface of the functional layer, and an end of the first bending portion away from the first body portion contacts the metal layer; or
wherein the metal layer comprises a second body portion and a second bending portion connected to the second body portion, the second body portion is parallel to the functional layer, the second bending portion is bent toward the adhesive layer relative to the second body portion and covers a side surface of the functional layer, and an end of the second bending portion away from the second body portion contacts the adhesive layer.

7. The heat dissipation film according to claim 1, wherein a resistance value of the adhesive layer is in a range of 104 to 105 ohms.

8. The heat dissipation film according to claim 1, wherein along a direction perpendicular to a surface of the heat dissipation film, a thickness of the adhesive layer is in a range of 25 to 35 microns.

9. A display module, comprising:
a display panel;
a back film arranged on a backlight side of the display panel; and
the heat dissipation film according to claim 1, wherein an adhesive layer of the heat dissipation film is bonded to a side of the back film away from the display panel, and on at least one side of the heat dissipation film, the adhesive layer of the heat dissipation film contacts a metal layer.

10. The display module according to claim 9, wherein the display panel has a curved side, at least one side of the heat dissipation film is a side directly opposite to the curved side, and the adhesive layer covers a side surface of a functional layer of the heat dissipation film and contacts the metal layer.

11. The display module according to claim 10, wherein the adhesive layer comprises an overflow portion configured to cover the side surface of the functional layer and contact the metal layer; and the overflow portion is formed by squeezing the adhesive layer during a bonding process.

12. The display module according to claim 11, wherein the functional layer comprises: a foam layer and a support layer arranged in stack; an edge of the support layer is retracted relative to an edge of the foam layer and an edge of the metal layer, and the overflow portion covers a side surface of the foam layer and a side surface of the support layer, and contacts the metal layer.

13. The display module according to claim 10, wherein the adhesive layer comprises an overlapping portion, the overlapping portion is a portion exceeding edges of other film layers of the heat dissipation film, and the overlapping portion covers the side surface of the functional layer and contacts the metal layer.

14. The display module according to claim 13, wherein the functional layer comprises: a foam layer and a support layer arranged in stack, an edge of the support layer exceeds an edge of the foam layer, an edge of the metal layer exceeds the edge of the support layer, and the overlapping portion covers a side surface of the foam layer and a side surface of the support layer, and contacts the metal layer.

15. The display module according to claim 9, wherein the at least one side of the heat dissipation film is any one or more sides of the heat dissipation film, the adhesive layer comprises: a first body portion and a first bending portion connected to the first body portion, the first body portion is parallel to the functional layer of the heat dissipation film, the first bending portion is bent toward the metal layer relative to the first body portion and covers a side surface of the functional layer, and an end of the first bending portion away from the first body portion contacts the metal layer; and
wherein the first body portion is bonded to a side of the back film away from the display panel.

16. The display module according to claim 9, wherein at least one side of the heat dissipation film is any one or more sides of the heat dissipation film, the metal layer comprises a second body portion and a second bending portion connected to the second body portion, the second body portion is parallel to the functional layer connected thereto, and the second bending portion is bent toward the adhesive layer relative to the second body portion and covers a side surface of the functional layer; and
wherein the adhesive layer comprises a first adhesive region and a second adhesive region, the first adhesive region is a region adhered to the functional layer, the second adhesive region is located outside the first adhesive region, one side of the second adhesive region is adhered to the back film, and the other side of the second adhesive region contacts an end of the second bending portion away from the second body portion.

17. A display apparatus, comprising: the display module according to any claim 9.
